(19) United States
(12) Patent Application Publication
(10) Pub. No.: US 2022/0239270 A1
(43) Pub. Date: Jul. 28, 2022

(54) 2D & 3D RF Lumped Element Devices for RF System in a Package Photoactive Glass Substrates

(71) Applicant: 3D Glass Solutions, Inc., Albuquerque, NM (US)

(72) Inventors: Jeb H. Flemming, Albuquerque, NM (US); Jeff A. Bullington, Orlando, FL (US); Kyle McWethy, Albuquerque, NM (US)

(21) Appl. No.: 17/717,743

(22) Filed: Apr. 11, 2022

Related U.S. Application Data
(63) Continuation-in-part of application No. 16/622,421, filed on Dec. 13, 2019, now Pat. No. 11,342,896.
(60) Provisional application No. 62/529,990, filed on Jul. 7, 2017.

(51) Int. Cl. H03H 3/00; H03H 7/06; H01P 1/32; H03H 7/46; H01P 5/12; C03C 15/00; C03C 17/10; C03B 32/02; C25D 3/38; C25D 5/02; C25D 7/12

(52) U.S. Cl. CPC H03H 3/00; H03H 7/06; H01P 1/32; H03H 7/46; H01P 5/12; C03C 15/00; C03C 2218/34; C03B 32/02; C25D 3/38; C25D 5/022; C25D 7/123; C03C 2217/253; C03C 2218/31; C03C 17/10

(57) ABSTRACT

The present invention includes a method for creating a system-in-package in or on photodefinable glass including: providing a photodefinable glass substrate; masking a design layout comprising one or more structures to form one or more integrated lumped element devices as the system-in-package on or in a photodefinable glass substrate; transforming at least a portion of the photodefinable glass substrate to form a glass-crystalline substrate; etching the glass-crystalline substrate to form one or more channels in the glass-crystalline substrate; depositing, growing, or selectively etching a seed layer on a surface of the glass-crystalline substrate to enable electroplating of copper; and electroplating the copper to fill the one or more channels and to deposit copper on the surface of the photodefinable glass to form the one or more integrated lumped element devices.

### CROSS-REFERENCE TO RELATED APPLICATIONS

This application is a continuation-in-part of U.S. patent application Ser. No. 16/622,421 filed on Dec. 13, 2019, now U.S. Pat. No. ______, issued on ______, 2022, which application is the National Stage application of International Application No. PCT/US2018/039841, filed on Jun. 27, 2018 claiming the priority to U.S. Provisional Application No. 62/529,990 filed on Jul. 7, 2017, the contents of each of which are incorporated by reference herein.

### STATEMENT OF FEDERALLY FUNDED RESEARCH

None.

### TECHNICAL FIELD OF THE INVENTION

The present invention relates in general to the field of RF lumped element devices for RF system in a package photoactive glass substrates.

### BACKGROUND OF THE INVENTION

Without limiting the scope of the invention, its background is described in connection with RF lumped element devices.

Photosensitive glass structures have been suggested for a number of micromachining and microfabrication processes such as integrated electronic elements in conjunction with other elements systems or subsystems. Silicon microfabrication of traditional glass is expensive and low yield while injection modeling or embossing processes produce inconsistent shapes. Silicon microfabrication processes rely on expensive capital equipment; photolithography and reactive ion etching or ion beam milling tools generally cost in excess of one million dollars each and require an ultra-clean, high-production silicon fabrication facility costing millions to billions more. Injection molding and embossing are less costly methods of producing a three dimensional shapes but generate defects within the transfer or have differences due to the stochastic curing process. Ideal inductors would have zero resistance and zero capacitance. But, real inductors have “parasitic” resistance, inductance and capacitance.

Historically, inductor capacitance is called “inter-winding capacitance” based on the assumption that it is the result of charge separation between insulated coil windings. However, if the inductor is measured over a conducting ground plane, capacitance between the coil and the ground plane is also part of the measurement. The distance of the coil from the measurement ground plane and the effective dielectric constant of the measurement substrate affects the capacitance to ground. This partially explains how the test fixture affects the self-resonant frequency (SRF) measurement. The following equation shows how the SRF is related to inductance and capacitance in an LC circuit:

$$SRF = \frac{1}{2 π \sqrt{( LC )}} in Hz$$

where: L is the inductance in Henries, and C is the capacitance in Farads.

In addition to the additional inductance, capacitance and resistance cause losses from: (1) PCB interconnects; (2) Long metal redistribution line lengths; (3) Bond pads; (4) Solder balls; (5) Substrate losses and dielectric constant/loss tangent; and/or (6) inconsistent assembly.

From this equation, it is clear that in general, RF and/or microwave filters are made up of one or more coupled resonators and several different technologies can be used to make resonators/filters. The majority of the resonators/filters fall into one of three general categories: Lumped-Element, Microstrip Transmission Lines, and Coaxial Waveguide.

Lumped-element or inductor capacitor (LC) filters are the simplest resonator structure used in RF and microwave filters and other devices, e.g., lumped-element circuit consisting of parallel or series inductors and capacitors. An advantage of lumped-element filters/devices is that they can be very compact but the disadvantages are that they have a low quality factor, large level of distortion/noise and relatively poor performance. As such lumped-element devices are not considered a viable option in RF/Microwave applications.

In the book Lumped Elements for RF and Microwave Circuits by Inder Bahl published in 2003 it is stated that, “[a]n ideal lumped element is not realizable even at lower microwave frequencies because of the associated parasitic reactances due to fringing fields. At RF and microwave frequencies, each component has associated electric and magnetic fields and finite dissipative loss. Thus, such components store or release electric and magnetic energies across them and their resistance accounts for the dissipated power. The relative values of the C, L, and R components in these elements depend on the intended use of the LE. To describe their electrical behavior, equivalent circuit models for such components are commonly used. Lumped element equivalent circuit (EC) models consist of basic circuit elements (L, C, or R) with the associated parasitics denoted by subscripts. Accurate computer-aided design of MICs and MMICs requires a complete and accurate characterization of these components. This requires comprehensive models including the effect of ground plane, fringing fields, proximity effects, substrate material and thickness, conductor thickness, and associated mounting techniques and applications. Thus, an EC representation of a lumped element with its parasitics and their frequency-dependent characteristics is essential for accurate element modeling. An EC model consists of the circuit elements necessary to fully describe its response, including resonances, if any. Models can be developed using analytical, electromagnetic simulation, and measurement based methods. The early models of lumped elements were developed using analytical semiempirical equations. In 1943, Terman published an expression for the inductance of a thin metallic straight line that was later improved by Caulton et al., who added the effect of metallization thickness. Wheeler presented an approximate formula for the inductance of a circular spiral inductor with reasonably good accuracy at lower microwave frequencies. This formula has been extensively used in the design of microwave lumped circuits.” Others have discussed inductance calculations for several geometries. The theoretical modeling of microstrip inductors for MICs has usually been based on two methods: the lumped-element approach and the coupled-line approach. The lumped-element approach uses formulas for free-space inductance with ground plane effects. These frequency-independent formulas are useful only when the total length of the inductor is a small fraction of the operating wavelength and when interturn capacitance can be ignored. In the coupled-line approach, an inductor is analyzed using multiconductor coupled microstrip lines. This Lumped Elements for RF and Microwave Circuits technique predicts the spiral inductor's performance reasonably well for two turns and up to about 18 GHz. An earlier theory for the interdigital capacitor was published by Alley, and Joshi et al. presented modified formulas for these capacitors. Mondal reported a distributed model of the MIM capacitor based on the coupled-line approach. Pengelly et al. presented the first extensive results on different lumped elements on GaAs, including inductors and interdigital capacitors, with special emphasis on the Q-factor. Pettenpaul et al. reported lumped-element models using numerical solutions along with basic microstrip theory and network analysis. In general, analytical models are good for estimating the electrical performance of lumped elements. The realization of lumped L, C, R elements at microwave frequencies is possible by keeping the component size much smaller than the operating wavelength. However, when the component size becomes greater than 1/10, these components have undesirable associated parasitics such as resistance, capacitance, and inductance. At RF and higher frequencies, the reactances of the parasitics become more significant with increasing frequency, resulting in higher loss and spurious resonances. Thus, empirical expressions are not accurate enough to predict LE performance accurately. Once lumped elements are accurately characterized either by electromagnetic (EM) simulation or measurements, the parasitic reactances become an integral part of the component and their effects can be included in the design.

Recent advances in workstation computing power and user-friendly software make it possible to develop EM field simulators. These simulators play a significant role in the simulation of single and multilayer passive circuit elements such as transmission lines and their discontinuities; patches; multilayer components, namely, inductors, capacitors, resistors, via holes, airbridges, inductor transformers, packages, and so on; and passive coupling between various circuit elements. Accurate evaluation of the effects of radiation, surface waves and interaction between components on the performance of densely packed Monolithic Microwave Integrated Circuits (MMICs) can only be calculated using three-dimensional (3-D) EM simulators. The most commonly used method of developing accurate models for lumped elements is by measuring dc resistance and S-parameter data. This modeling approach gives quick and accurate results, although the results are generally limited to just the devices measured. EC model parameters are extracted by computer optimization, which correlates the measured dc and S-parameter data (one- or two-port data) up to 26 or 40 GHz depending on the application. The accuracy of the model parameter values can be as good as the measurement accuracy by using recently developed on-wafer calibration standards and techniques. The equivalent circuit models are valid mostly up to the first parallel resonant frequency (fᵣₑₛ). However, when a design is involved with harmonics, for example, a power amplifier with second and third harmonic terminations at the output, one requires either EM simulated data working up to the highest design frequency or a more complex model taking into account higher order resonances. If the operating frequency is lower than fᵣₑₛ/3, then the models discussed above are adequate. At RF and microwave frequencies, the resistance of LEs is quite different from their dc values due to the skin effect. When an RF signal is applied across a LE, due to the finite conductivity of the conductor material, EM fields penetrate a conductor only a limited depth along its cross section. The distance in the conductor over which the fields decrease to 1/e (about 36.9%) of the values at the surface is called depth of penetration, or skin depth. This effect is a function of frequency with the penetration depth decreasing with increasing frequency. The flow of RF current is limited to the surface only, resulting in higher RF surface resistance than the dc value. This effect is taken into account during accurate modeling of the resistive loss in the component.

Microstrip transmission lines, also known as striplines, can make good resonators/filters and offer a better compromise in terms of size and performance than lumped element filters. The processes used to manufacture microstrip circuits is very similar to the processes used to manufacture printed circuit boards using a precision thin-film process but require using quartz, ceramic, sapphire substrates and lower resistance metals such as gold to obtain the performance required for low power/loss RF applications.

Coaxial Waveguide (CW) filters provide higher Q factor than planar transmission lines, and are used in high performance RF applications. The coaxial resonators may make use of high-dielectric constant materials to reduce their size. The size of CW filter scale inversely to the frequency the size and can reach to less than 2 cm² at frequencies above 30 GHz on a ceramic substrate. The combination of a ceramic substrate and the physical size prevents the filter makes these filters expensive and large relative to other RF filters from and as such are not generally used in commercial portable, compact RF products.

One of the most common RF filters are surface acoustic wave (SAW) and/or bulk acoustic wave (BAW). Both SAW and BAW exhibit decreased signal to noise ratios as the frequency of operation exceeds the speed of sound in the piezoelectric material. Single crystal BAW devices have been shown to have higher performance but also suffer from a dramatic collapse of the signal to noise when the frequencies exceed the speed of sound of the piezoelectric material. The speed of sound of the piezoelectric material used in SAW and BAW filters limits their application to frequencies less than 3 GHz.

Despite all of these advances, a need remains for improvements to existing devices that have increased signal to noise ratio, that are easy and inexpensive to build, and that eliminate losses from: (1) PCB interconnects; (2) Long metal redistribution line lengths; (3) Bond pads; (4) Solder balls; (5) Substrate losses and dielectric constant/loss tangent; and/or (6) inconsistent assembly.

### SUMMARY OF THE INVENTION

In one embodiment, the present invention includes a method for creating a system in a package with integrated lumped element devices formed as a system-in-package (SiP) in or on photo-definable glass comprising the steps of: masking a design layout comprising one or more structures to form one or more electrical components on or in a photosensitive glass substrate; exposing at least one portion of the photosensitive glass substrate to an activating energy source; heating the photosensitive glass substrate for at least ten minutes above its glass transition temperature; cooling the photosensitive glass substrate to transform at least a part of the exposed glass to a crystalline material to form a glass-crystalline substrate; etching the glass-crystalline substrate with an etchant solution to form one or more channels in the device, wherein the glass-crystalline substrate adjacent to the trenches, which may optionally be converted to a ceramic phase; and depositing, growing, or selectively etching a seed layer on a surface of the glass-crystalline substrate exposed during the etching step to enable electroplating of copper to fill the trenches and deposit on the surface of the photodefinable glass, wherein the integrated lumped element devices reduces the parasitic noise and losses by at least 25% from a package lumped element device mount to a system-in-package (SiP) in or on photo-definable glass when compared to an equivalent surface mounted device. In one aspect, the method further comprises forming an isolator with integrated lump element devices is in a SiP. In another aspect, the method further comprises forming a circulator with integrated lump element devices in a SiP. In another aspect, the method further comprises forming an RF filter with integrated lump element devices in a SiP. In another aspect, the method further comprises forming at least one of a low pass, high pass filter, notch filter, band pass filter, transformer, circulator, isolator, with integrated lump element devices in a SiP. In another aspect, the method further comprises forming a power combiner, a power splitter RF Circuit in or on the photo-definable glass substrate. In another aspect, the method further comprises forming an SiP RF Circuit that eliminates at least 30% of the RF parasitic signal loss when compared to an equivalent surface mounted device. In another aspect, the method further comprises forming an SiP RF Circuit that eliminates at least 35% of the RF parasitic signal loss when compared to an equivalent surface mounted device (the loss associated with the packaging a mount elements to a substrate). In another aspect, the method further comprises forming an SiP RF Circuit that eliminates at least 50% of the RF parasitic signal loss when compared to an equivalent surface mounted device. In another aspect, the method further comprises forming one or more RF Filters, RF Circulators, RF Isolators, Antenna, Impedance Matching Elements, 50 Ohm Termination Elements, Integrated Ground Planes, RF Shielding Elements, EMI Shielding Elements, RF Combiners, RF Splitters, Transformers, Switches, power splitters, power combiners, and/or Diplexors.

Another embodiment of the present invention includes a package lumped element device mount to a system-in-package (SiP) in or on photo-definable glass made by the method described hereinabove. In one aspect, the device is an isolator with integrated lump element devices and is in a SiP. In another aspect, the device is a circulator with integrated lump element devices and is in a SiP. In another aspect, the device is an RF filter with integrated lump element devices and is in a SiP. In another aspect, the device is at least one of a low pass, high pass filter, notch filter, band pass filter, transformer, circulator, isolator, with integrated lump element devices and is in a SiP. In another aspect, the device is a power combiner, a power splitter RF Circuit in or on the photo-definable glass substrate. In another aspect, the device is a SiP RF Circuit that eliminates at least 30% of the RF parasitic signal loss when compared to an equivalent surface mounted device. In another aspect, the device is a SiP RF Circuit that eliminates at least 35% of the RF parasitic signal loss when compared to an equivalent surface mounted device. In another aspect, the method further comprises forming an SiP RF Circuit that eliminates at least 50% of the RF parasitic signal loss when compared to an equivalent surface mounted device. In another aspect, the device is one or more RF Filters, RF Circulators, RF Isolators, Antenna, Impedance Matching Elements, 50 Ohm Termination Elements, Integrated Ground Planes, RF Shielding Elements, EMI Shielding Elements, RF Combiners, RF Splitters, Transformers, Switches, power splitters, power combiners, and/or Diplexors.

In yet another embodiment, the present invention includes a method for creating a system in a package with integrated lumped element devices formed as a system-in-package (SiP) in or on photo-definable glass comprising the steps of: masking a design layout comprising one or more structures to form one or more electrical components on or in a photosensitive glass substrate; transforming at least a part of the exposed glass to a crystalline material to form a glass-crystalline substrate; etching the glass-crystalline substrate with an etchant solution to form one or more channels in the device, wherein the glass-crystalline substrate adjacent to the trenches, which may optionally be converted to a ceramic phase; and depositing, growing, or selectively etching a seed layer on a surface of the glass-crystalline substrate exposed during the etching step to enable electroplating of copper to fill the trenches and deposit on the surface of the photodefinable glass, wherein the integrated lumped element devices reduces the parasitic noise and losses by at least 25% from a package lumped element device mount to a system-in-package (SiP) in or on photo-definable glass when compared to an equivalent surface mounted device. In one aspect, the method further comprises forming an isolator with integrated lump element devices is in a SiP. In another aspect, the method further comprises forming a circulator with integrated lump element devices in a SiP. In another aspect, the method further comprises forming an RF filter with integrated lump element devices in a SiP. In another aspect, the method further comprises forming at least one of a low pass, high pass filter, notch filter, band pass filter, transformer, circulator, isolator, with integrated lump element devices in a SiP. In another aspect, the method further comprises forming a power combiner, a power splitter RF Circuit in or on the photo-definable glass substrate. In another aspect, the method further comprises forming an SiP RF Circuit that eliminates at least 30% of the RF parasitic signal loss when compared to an equivalent surface mounted device. In another aspect, the method further comprises forming an SiP RF Circuit that eliminates at least 35% of the RF parasitic signal loss when compared to an equivalent surface mounted device. In another aspect, the method further comprises forming an SiP RF Circuit that eliminates at least 50% of the RF parasitic signal loss when compared to an equivalent surface mounted device. In another aspect, the method further comprises forming one or more RF Filters, RF Circulators, RF Isolators, Antenna, Impedance Matching Elements, 50 Ohm Termination Elements, Integrated Ground Planes, RF Shielding Elements, EMI Shielding Elements, RF Combiners, RF Splitters, Transformers, Switches, power splitters, power combiners, and/or Diplexors.

Another embodiment of the present invention includes a package lumped element device mount to a system-in-package (SiP) in or on photo-definable glass made by the method described hereinabove. In one aspect, the device is an isolator with integrated lump element devices and is in a SiP. In another aspect, the device is a circulator with integrated lump element devices and is in a SiP. In another aspect, the device is an RF filter with integrated lump element devices and is in a SiP. In another aspect, the device is at least one of a low pass, high pass filter, notch filter, band pass filter, transformer, circulator, isolator, with integrated lump element devices and is in a SiP. In another aspect, the device is a power combiner, a power splitter RF Circuit in or on the photo-definable glass substrate. In another aspect, the device is a SiP RF Circuit that eliminates at least 30% of the RF parasitic signal associated with the packaging a mount elements to a substrate. In another aspect, the device is a SiP RF Circuit that eliminates at least 35% of the RF parasitic signal associated with the packaging a mount elements to a substrate. In another aspect, the device is one or more RF Filters, RF Circulators, RF Isolators, Antenna, Impedance Matching Elements, 50 Ohm Termination Elements, Integrated Ground Planes, RF Shielding Elements, EMI Shielding Elements, RF Combiners, RF Splitters, Transformers, Switches, power splitters, power combiners, and/or Diplexors.

Another embodiment of the invention includes a method for creating a system-in-package formed in or on photodefinable glass including: providing a photodefinable glass substrate; masking a design layout including one or more structures to form one or more integrated lumped element devices as the system-in-package on or in a photodefinable glass substrate; transforming at least a portion of the photodefinable glass substrate to a crystalline material to form a glass-crystalline substrate; etching the glass-crystalline substrate with an etchant solution to form one or more channels in the glass-crystalline substrate; depositing, growing, or selectively etching a seed layer on a surface of the glass-crystalline substrate exposed during the etching step to enable electroplating of copper to fill the one or more channels and to deposit the copper on the surface of the photodefinable glass to form the one or more integrated lumped element devices; and electroplating the copper to fill the one or more channels and to deposit copper on the surface of the photodefinable glass to form the one or more integrated lumped element devices. In one aspect, the photodefinable glass substrate includes silica, lithium oxide, aluminum oxide, and cerium oxide. In another aspect, the method further includes converting the glass-crystalline substrate adjacent to the one or more channels to a ceramic phase. In another aspect, the step of transforming at least a portion of the photodefinable glass substrate includes: exposing at least a portion of the photodefinable glass substrate to an activating energy source; heating the photodefinable glass substrate for at least ten minutes above a glass transition temperature thereof; and cooling the photodefinable glass substrate to transform the at least a portion of the exposed photodefinable glass substrate to a crystalline material to form the glass-crystalline substrate. In another aspect, an anisotropic-etch ratio of an exposed portion to an unexposed portion is at least 30:1. In another aspect, the one or more integrated lumped system elements form an RF circuit that eliminates at least 25%, 30%, 35%, 40%, 45%, or 50% of an RF parasitic signal loss when compared to the equivalent surface-mounted device that is not on or in photodefinable glass. In another aspect, the one or more integrated lumped element devices form one or more isolators, one or more circulators, or one or more radio frequency (RF) filters including a low-pass filter, a high-pass filter, a notch filter, or a band-pass filter. In another aspect, the one or more integrated lumped system elements form one or more devices including an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer.

Another embodiment of the invention includes a system-in-package made by a method including: providing a photodefinable glass substrate; masking a design layout including one or more structures to form one or more integrated lumped element devices as the system-in-package on or in a photodefinable glass substrate; transforming at least a portion of the photodefinable glass substrate to a crystalline material to form a glass-crystalline substrate; etching the glass-crystalline substrate with an etchant solution to form one or more channels in the glass-crystalline substrate; depositing, growing, or selectively etching a seed layer on a surface of the glass-crystalline substrate exposed during the etching step to enable electroplating of copper to fill the one or more channels and to deposit the copper on the surface of the photodefinable glass to form the one or more integrated lumped element devices; and electroplating the copper to fill the one or more channels and to deposit copper on the surface of the photodefinable glass to form the one or more integrated lumped element devices. In one aspect, the photodefinable glass substrate includes silica, lithium oxide, aluminum oxide, and cerium oxide. In another aspect, the method further includes converting the glass-crystalline substrate adjacent to the one or more channels to a ceramic phase. In another aspect, the step of transforming at least a portion of the photodefinable glass substrate includes: exposing at least a portion of the photodefinable glass substrate to an activating energy source; heating the photodefinable glass substrate for at least ten minutes above a glass transition temperature thereof; and cooling the photodefinable glass substrate to transform the at least a portion of the exposed photodefinable glass substrate to a crystalline material to form the glass-crystalline substrate. In another aspect, an anisotropic-etch ratio of an exposed portion to an unexposed portion is at least 30:1. In another aspect, the one or more integrated lumped system elements form an RF circuit that eliminates at least 25%, 30%, 35%, 40%, 45%, or 50% of an RF parasitic signal loss when compared to the equivalent surface-mounted device that is not on or in photodefinable glass. In another aspect, the one or more integrated lumped element devices form one or more isolators, one or more circulators, or one or more radio frequency (RF) filters including a low-pass filter, a high-pass filter, a notch filter, or a band-pass filter. In another aspect, the one or more integrated lumped system elements form one or more devices including an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer.

Another embodiment of the invention includes a photodefinable glass substrate; and one or more integrated lumped element devices comprising one or more resistors, one or more capacitors, one or more inductors, or a combination thereof formed on or in the photodefinable glass substrate as a system-in-package. In one aspect, the photodefinable glass substrate comprises silica, lithium oxide, aluminum oxide, and cerium oxide. In another aspect, the one or more integrated lumped element devices form one or more isolators, one or more circulators, or one or more radio frequency (RF) filters comprising a low-pass filter, a high-pass filter, a notch filter, or a band-pass filter. In another aspect, the one or more integrated lumped system elements form one or more devices comprising an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer. In another aspect, the one or more integrated lumped system elements form an RF circuit that eliminates at least 25%, 30%, 35%, 40%, 45%, or 50% of an RF parasitic signal loss when compared to an equivalent surface-mounted device that is not on or in photodefinable glass.

### BRIEF DESCRIPTION OF THE DRAWINGS

For a more complete understanding of the features and advantages of the present invention, reference is now made to the detailed description of the invention along with the accompanying figures and in which:

FIG. 1A is a graph that shows the impact of the parasitic signals/losses capacitance on the performance of a capacitor in a system in a package (SiP) vs a Surface-Mount Technology (SMT) of the present invention.

FIG. 1B is a graph that shows the impact of the parasitic signals/losses on the performance of a inductor in a SiP vs an SMT of the present invention.

FIG. 2A is a graph that shows the performance of a 30 GHz Ban Pass filter and RF distortions in a Surface Mount Package on a PCB of the present invention.

FIG. 2B is a graph that shows the performance of a 28 GHz SiP Ban Pass filter of the present invention.

FIG. 2C is a graph that shows the performance of the SiP based 2.5 GHz Low Pass Filter of the present invention.

FIG. 2D is an image of the SiP based 2.5 GHz Low Pass Filter of the present invention.

FIG. 3A is a graph that shows the performance of the SiP based 19 GHz Band Pass Filter of the present invention.

FIG. 3B is an image of the SiP based 19 GHz Band Pass Filter of the present invention.

FIG. 4A is a graph that shows the performance of the SiP based 24 GHz Band Pass Filter of the present invention.

FIG. 4B is an image of the SiP based 24 GHz Band Pass Filter of the present invention.

FIG. 5A is a graph that shows the performance of the SiP based 33 GHz Low Pass Filter of the present invention.

FIG. 5B shows the image of the SiP based 33 GHz Low Pass Filter of the present invention.

FIG. 6A is a graph that shows the performance of the SiP based 28 GHz Band Pass Filter of the present invention.

FIG. 6B shows the image of the SiP based 28 GHz Band Pass Filter of the present invention.

FIG. 7A is a graph that shows the performance of the SiP based 7 GHz Band Pass Filter of the present invention.

FIG. 7B shows the image of several SiP based 7 GHz Band Pass Filter of the present invention.

FIG. 8 is a graph that shows the insertion loss of SiP based Filters of the present invention.

FIG. 9 shows a Doherty Amplifier design including the lumped elements of the present invention.

FIG. 10 shows a power divider/combiner.

FIG. 11 shows a lumped element circulator when a termination resistor is connected to the circulator, it becomes an isolator.

FIG. 12 shows glass based SiP with integrated lumped element devices of the present invention. The SiP is approximately 0.5 cm×0.5 cm.

FIG. 13 shows a sampling of glass based SiPs with integrated lumped element devices of the present invention. Depending on the size of the SiP there can be a great number of SiPs on a single wafer.

FIGS. 14A-14F show a process of making devices using the present invention.

FIGS. 15A-15F show further processing steps for making a device using the present invention.

FIG. 16 shows a flowchart of a method embodiment of the invention.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not limit the invention, except as outlined in the claims.

The present invention eliminates the parasitic losses and signals associated with lumped element devices in the RF domain. Lumped element devices or an array of lumped element devices consist of capacitors, inductors, and resistors to implement a wide number of electronic devices and functions including: filters (band-pass, band-stop, high-pass, notch, low-pass filter), circulators, antennas, power conditioners, power combiners, power splitters, matching networks, isolators and/or Doherty power amplifiers in a photo definable glass ceramic system in a system-in-a-package (SiP) for microwave and radiofrequency applications that eliminates or greatly reduce parasitic signals or losses. The parasitic signals or losses are generated from the antenna effects combined with the inductance, capacitance and resistance from the packaging, solder bonding (ball grid), electronic connectors (wire), electrical bond pads and mounting elements that attach the packaged lumped element devices to the SiP. The distorted signals or losses are transmitted to other RF devices on the printed circuit board or substrate. There is sufficient variation in the traditional packaging and mounting of lumped elements to create large performance variations from the actual intended performance. These variations appear to be random due to the subtle differences in the packaging that force RF products to endure a large number of design iterations and/or manual trimming/correction to create a final RF circuit that meets the desired operating envelope. Eliminating the distortion associated with the RF packaging and the mounting elements allows the RF filter device to preform as designed/simulated. Integrating lumped element devices into a photodefinable glass ceramic SiP enables the circuit to perform as designed and simulated through the entire RF spectrum. These lumped element device structures consist of both the vertical as well as horizontal planes either separately or at the same time to form two or three-dimensional lumped element devices with design to device parity, lower loss, low signal distortion, reduced parasitic capacitance, reduced cost, and smaller physical size.

As described in the background, photosensitive glass structures have been suggested for a number of micromachining and microfabrication processes such as integrated electronic elements in conjunction with other elements systems or subsystems. The present invention has advantages over silicon microfabrication of traditional glass that is expensive and low yield while injection modeling or embossing processes produce inconsistent shapes. The present invention has additional advantages over silicon microfabrication processes that rely on expensive capital equipment; photolithography and reactive ion etching or ion beam milling tools that generally cost in excess of one million dollars each and require an ultra-clean, high-production silicon fabrication facility costing millions to billions more. The present invention also overcomes the problems with injection molding and embossing that generate defects within the transfer or have differences due to the stochastic curing process. Ideal inductors would have zero resistance and zero capacitance. But, real inductors have “parasitic” resistance, inductors and capacitance. The first self-resonant frequency of an inductor is the lowest frequency at which an inductor resonates with its self-capacitance. The first resonance can be modeled by a parallel combination of inductance and capacitance. A resistor “R1” limits impedance near the resonant frequency at the self-resonant frequency (SRF) of an inductor, where all of the following conditions are met: (1) The input impedance is at its peak; (2) the phase angle of the input impedance is zero, crossing from positive (inductive) to negative (capacitive); (3) since the phase angle is zero, the Q is zero; (4) the effective inductance is zero, since the negative capacitive reactance (Xc=1/jωk) just cancels the positive inductive reactance (XL=jωL); (5) the 2-port insertion loss (e.g. S21 dB) is a maximum, which corresponds to the minimum in the plot of frequency vs. S21 dB; and (6) the 2-port phase (e.g. S21) angle is zero, crossing from negative at lower frequencies to positive at higher frequencies.

To address these needs, the present inventors developed a glass ceramic (APEX® Glass ceramic) as a novel packaging and substrate material for semiconductors, RF electronics, microwave electronics, and optical imaging. APEX® Glass ceramic is processed using first generation semiconductor equipment in a simple three step process and the final material can be fashioned into either glass, ceramic, or contain regions of both glass and ceramic. The APEX® Glass ceramic enables the creation of an SiP that includes one or part of the following: easily fabricated high density vias, electronic devices including; Inductors, Capacitors, Resistors, Transmission Lines, Coax Lines, Antenna, Microprocessor, Memory, Amplifier, Transistors, matching networks, RF Filters, RF Circulators, RF Isolators, Impedance Matching Elements, 50 Ohm Termination Elements, Integrated Ground Planes, RF Shielding Elements, EMI Shielding Elements, RF Combiners, RF Splitters, Transformers, Switches, Multiplexors, and/or Diplexers.

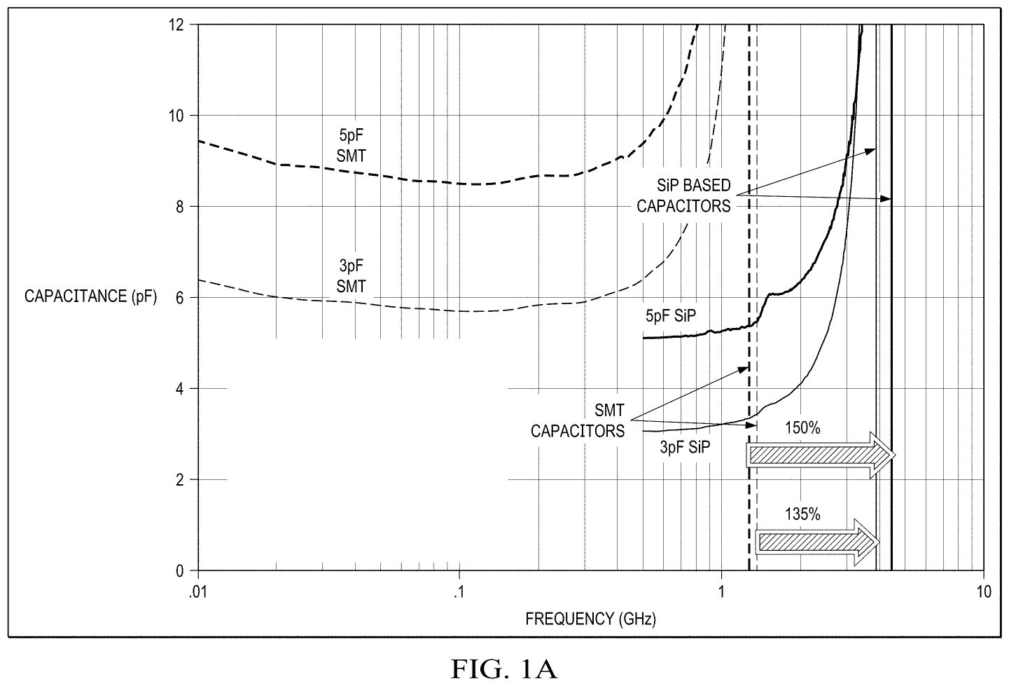

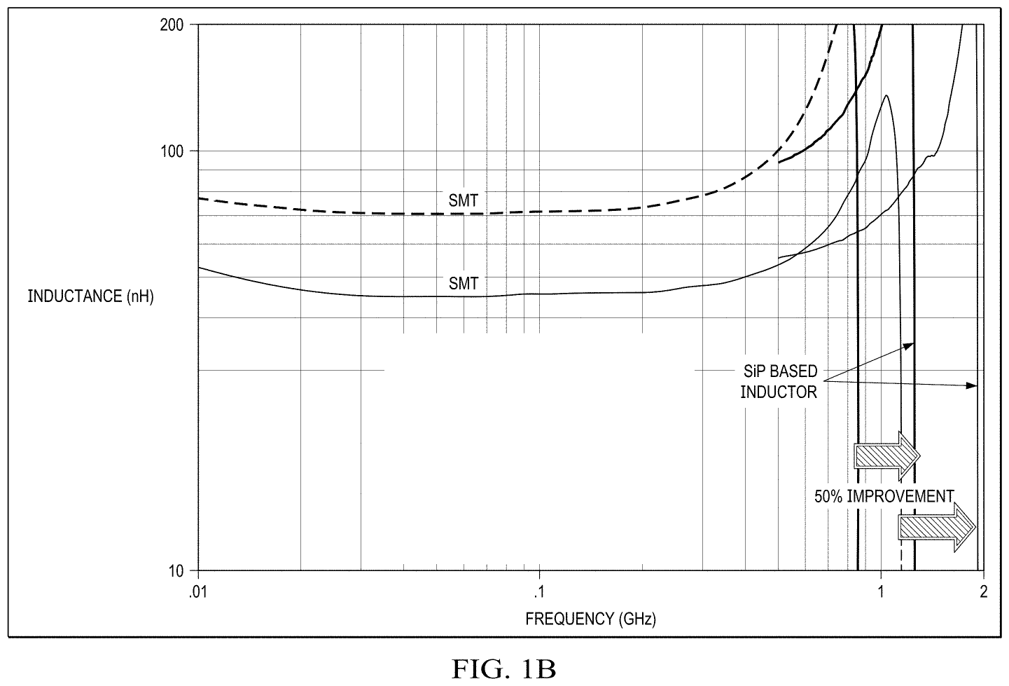

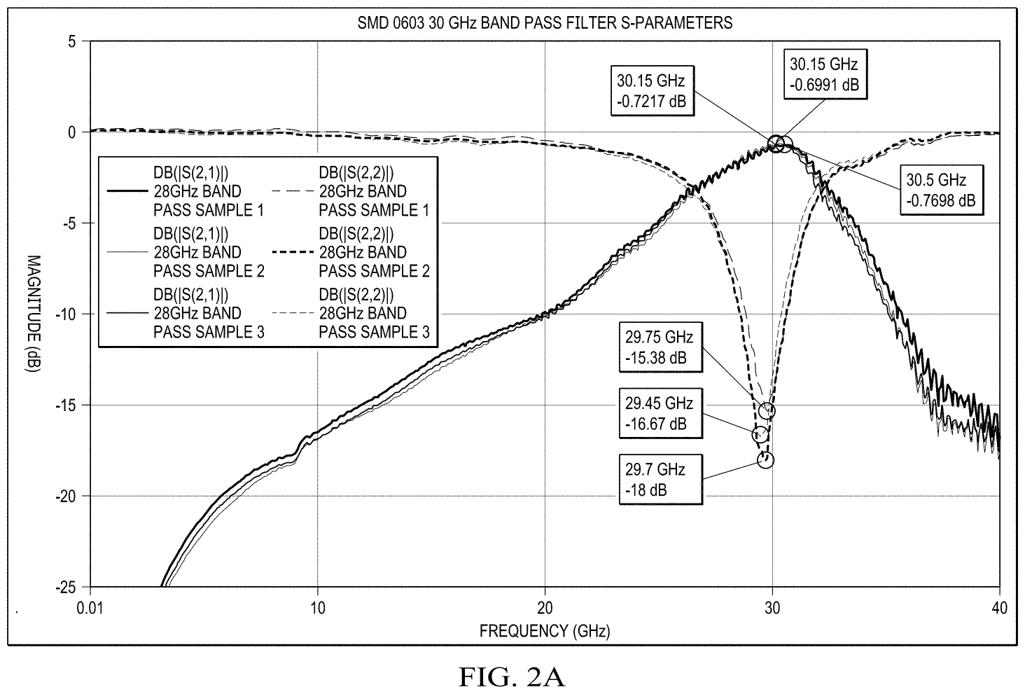

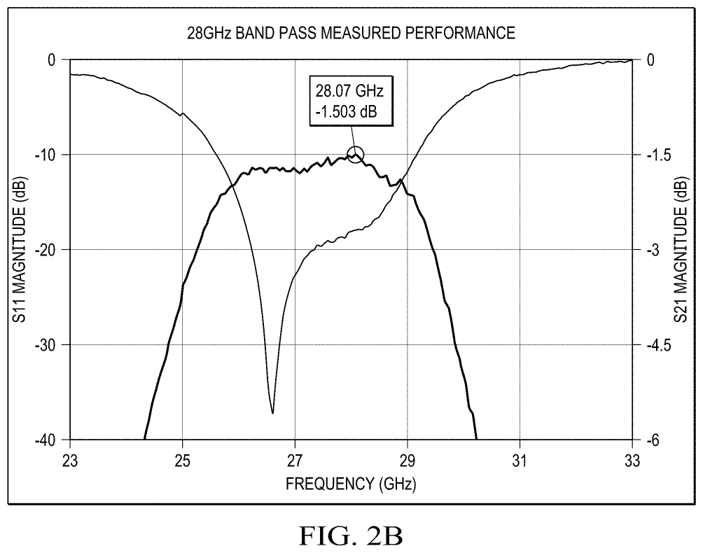

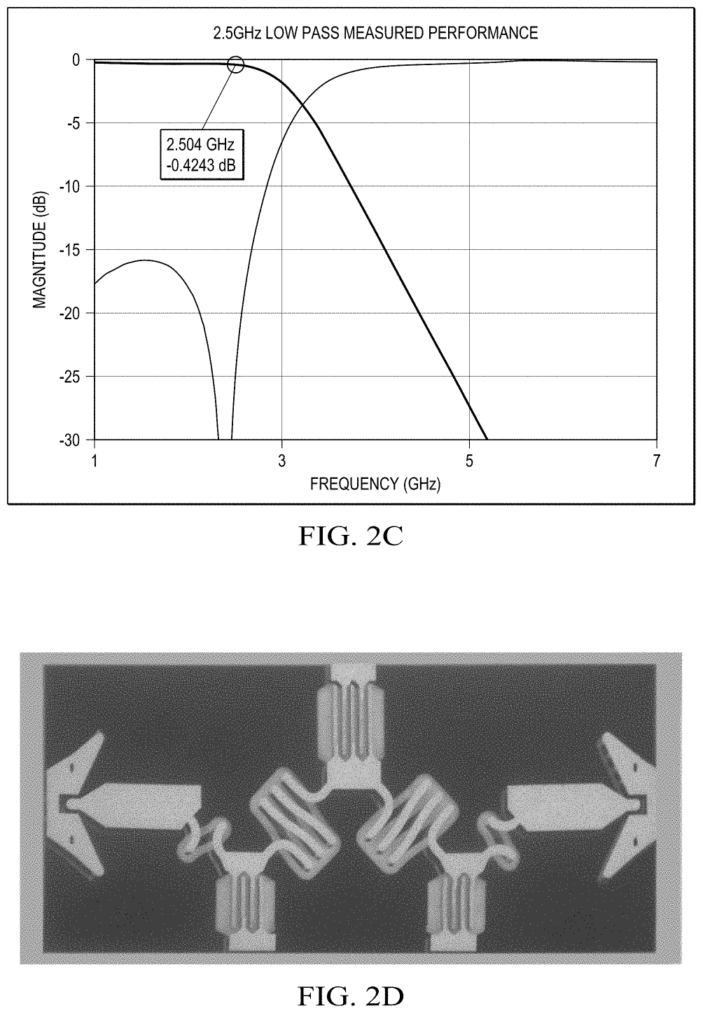

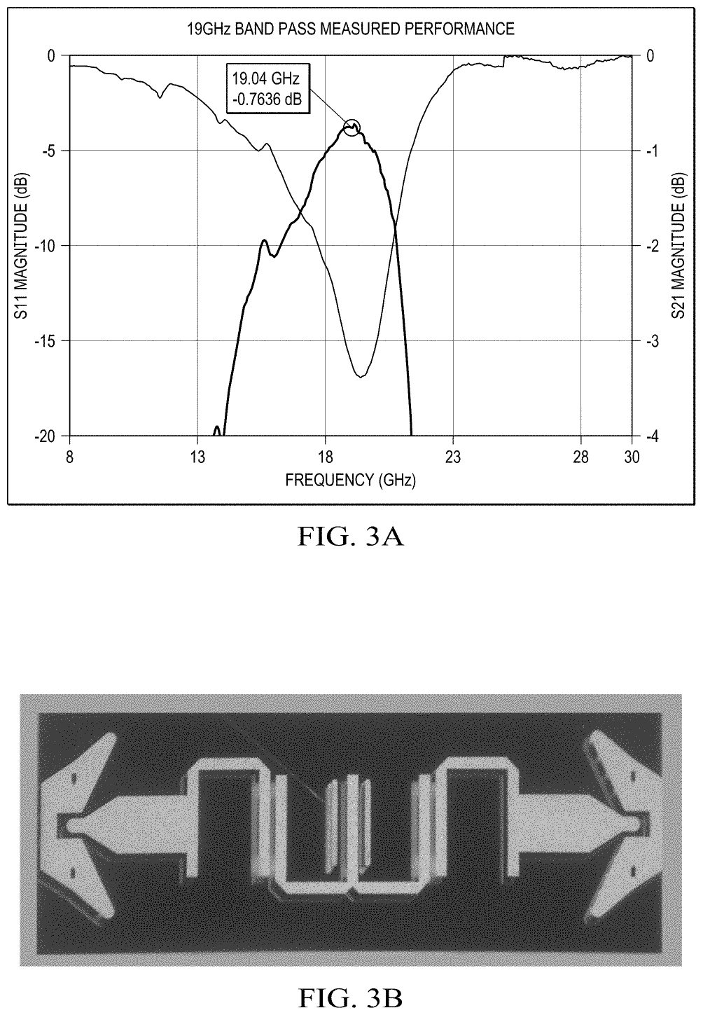

FIG. 1A shows test results for the same 3 pF and 5 pF capacitors. One set of capacitors were integrated and tested on a glass SiP. The other set of capacitors was packaged in a Surface-Mount Technology (SMT) and tested. The resulting data showed that the SiP integrated capacitor had between 150% and 135% higher SRF compared to the same capacitors packaged SMT, thus significantly improving on the prior art. The improvement in the performance is due to the removal of losses from bonding pads, ball bond, embedded leads, substrate and other parasitic effects associated with the SMT packaging. FIG. 1B shows the performance between two inductors (56 nH and 95 nH) measured in either SMT or integrated SiP. SiP based Inductors have a 50% higher SRF than SMT parts due to the removal of parasitic losses or signals associated with capacitance generated by the pads of the SMT packaging. On average integrated SiP components have a 50% higher SRF compared to the exact same part as an SMT. As the performance differences between the integrated SiP devices relative to the SMT devices are measured in dB, one can add the parasitic losses or signals associated with the use of a combination inductors and capacitors realized in filters, Doherty Amplifiers, circulators, isolators, antennas, power splitters, power combiners in addition to other RF/Microwave components used to make a system in a package. The combining of losses can be seen in FIGS. 2A to 2D. FIGS. 2A and 2B show the difference between a lumped element filter's performance integrated into a SiP and the other packaged in a surface mount device (SMD) package. FIG. 1A shows the signal for a lumped element bandpass filter in the SMD package mounted on a printed circuit board based SiP. FIG. 1B shows the signal for the same lumped element bandpass filter integrated directly into the glass based SiP. The normalized difference between the areas under performance curves of FIGS. 1A and 1B is approximately 200%. This shows that the use of RF lumped element device integrated directly into the SiP substrate reduces or eliminates the parasitic noise and losses by up to 200%, eliminating the losses, distortion/noise, parasitic signals and poor performance quality factor. The SiP based lumped element devices can have capacitors with quality factors much greater than 80 with inductors with quality factors much greater than 120. The enhanced performance of lumped element devices that are integrated directly into the SiP have demonstrated dramatically improved functionality in RF/Microwave device that can now be coupled with small feature size. The directly integrated lumped element based devices into or on to the SiP include but are not limited to: RF Filters, RF Circulators, RF Isolators, Antennas, Impedance Matching Elements, 50 Ohm Termination Elements, Integrated Ground Planes, RF Shielding Elements, EMI Shielding Elements, RF Combiners, RF Splitters, Transformers, Switches, power splitters, power combiners, and/or Diplexors. These directly integrated lumped element devices on the SiP are connected with integrated circuits devices. These integrated circuits devices include but are not limited to: microprocessors, multiplexers, switches, amplifiers, and memories. FIG. 3A is a graph that shows the performance of the SiP based 19 GHz Band Pass Filter of the present invention. FIG. 3B is an image of the SiP based 19 GHz Band Pass Filter of the present invention.

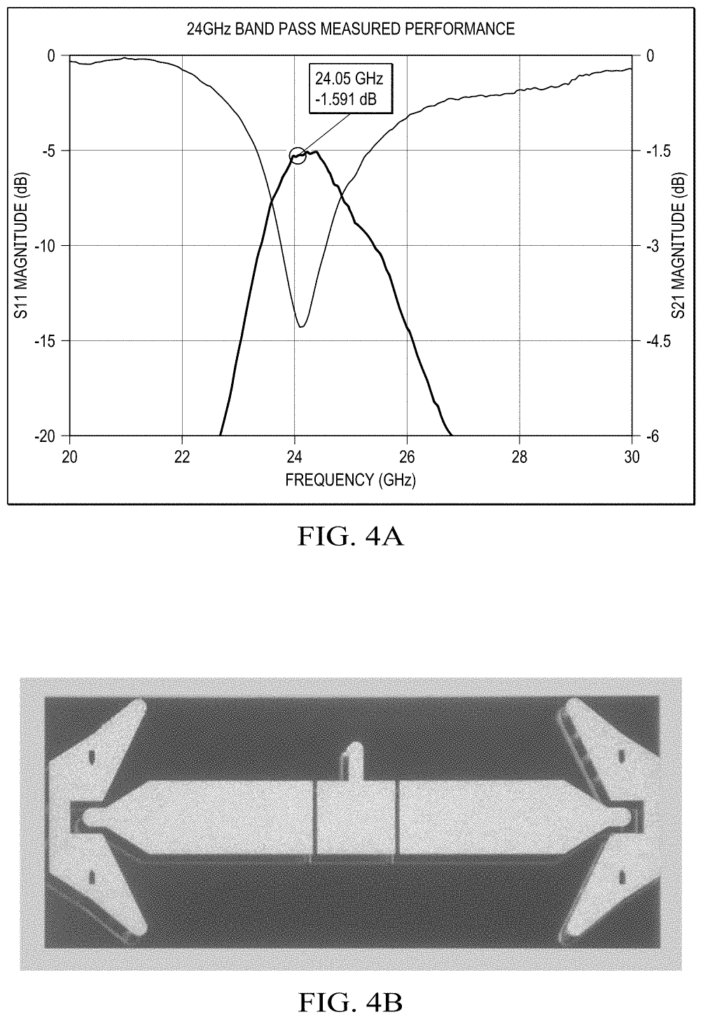

FIG. 4A is a graph that shows the performance of the SiP based 24 GHz Band Pass Filter of the present invention. The present invention improved the signal by 150% and 135% for the SiP of the present invention versus SMT when measuring capacitance versus frequency. FIG. 4B is a graph that shows the performance of the SiP based 24 GHz Band Pass Filter. The present invention improved the signal by 50% using the SiP of the present invention when compared to SMT when measuring inductance versus frequency.

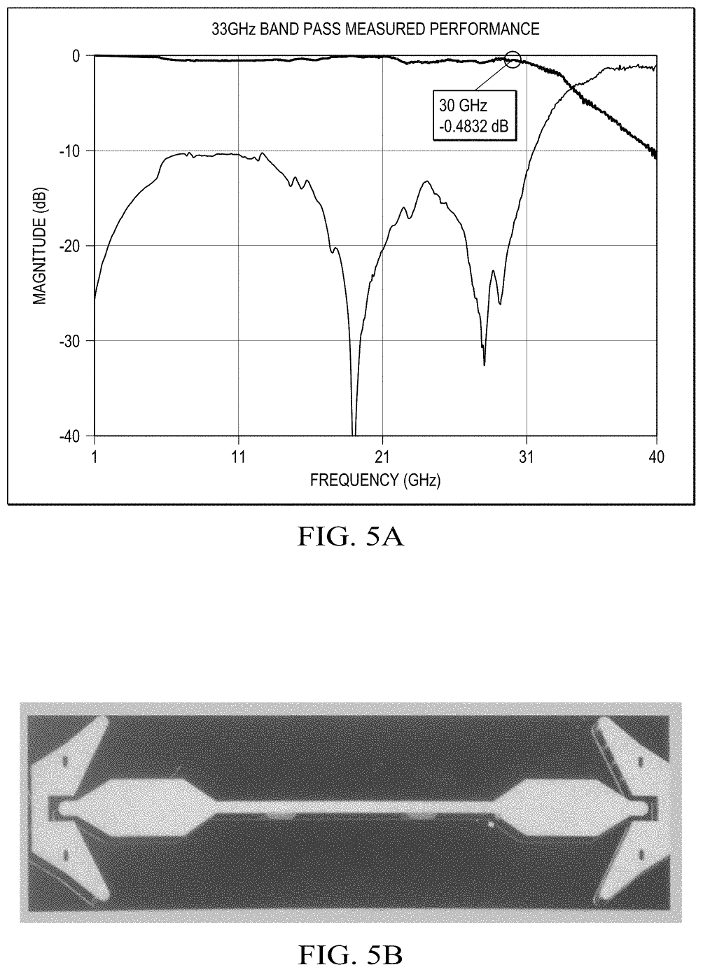

FIG. 5A is a graph that shows the performance of the SiP based 33 GHz Low Pass Filter of the present invention. FIG. 5B shows the image of the SiP based 33 GHz Low Pass Filter of the present invention.

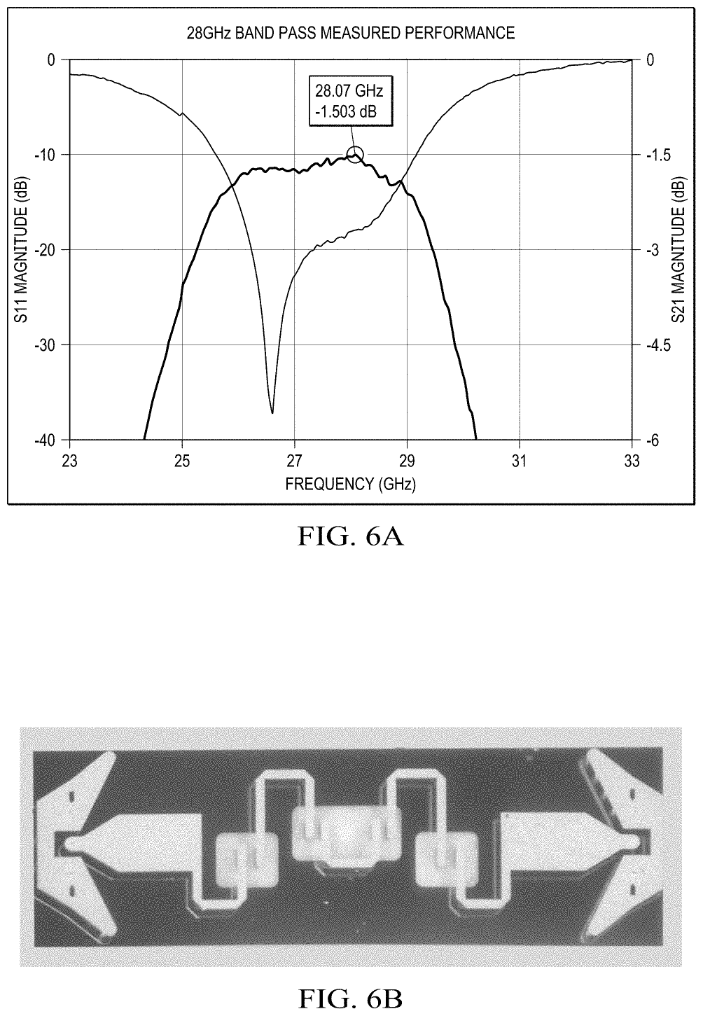

FIG. 6A is a graph that shows the performance of the SiP based 28 GHz Band Pass Filter of the present invention. FIG. 6B shows the image of the SiP based 28 GHz Band Pass Filter of the present invention.

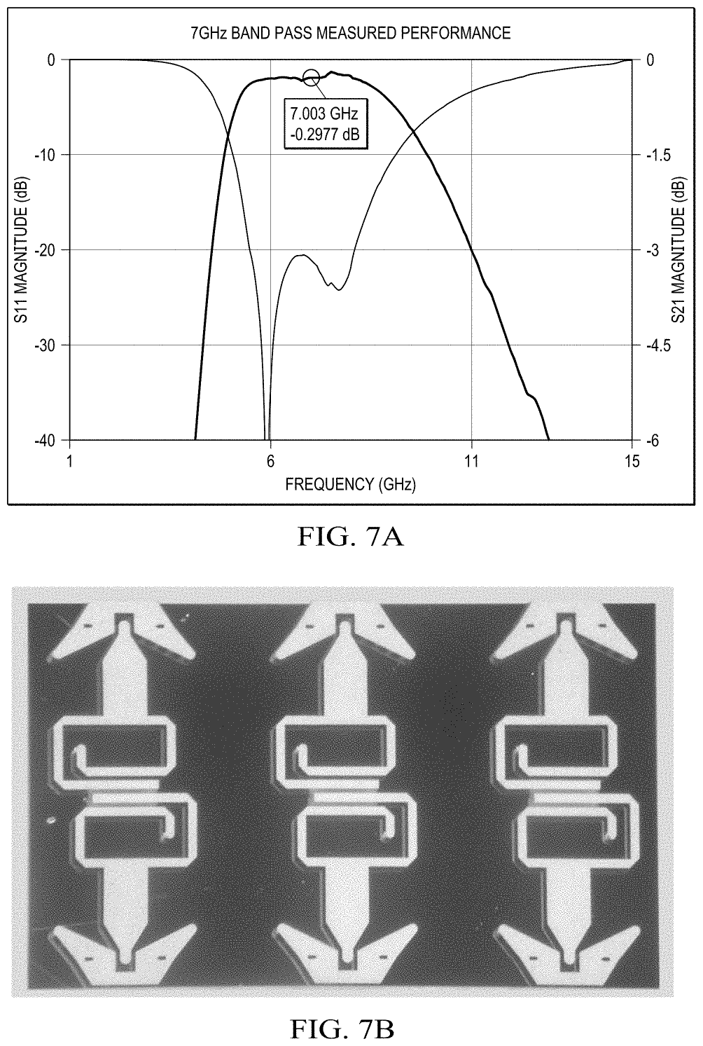

FIG. 7A is a graph that shows the performance of the SiP based 7 GHz Band Pass Filter of the present invention. FIG. 7B shows the image of several SiP based 7 GHz Band Pass Filter of the present invention.

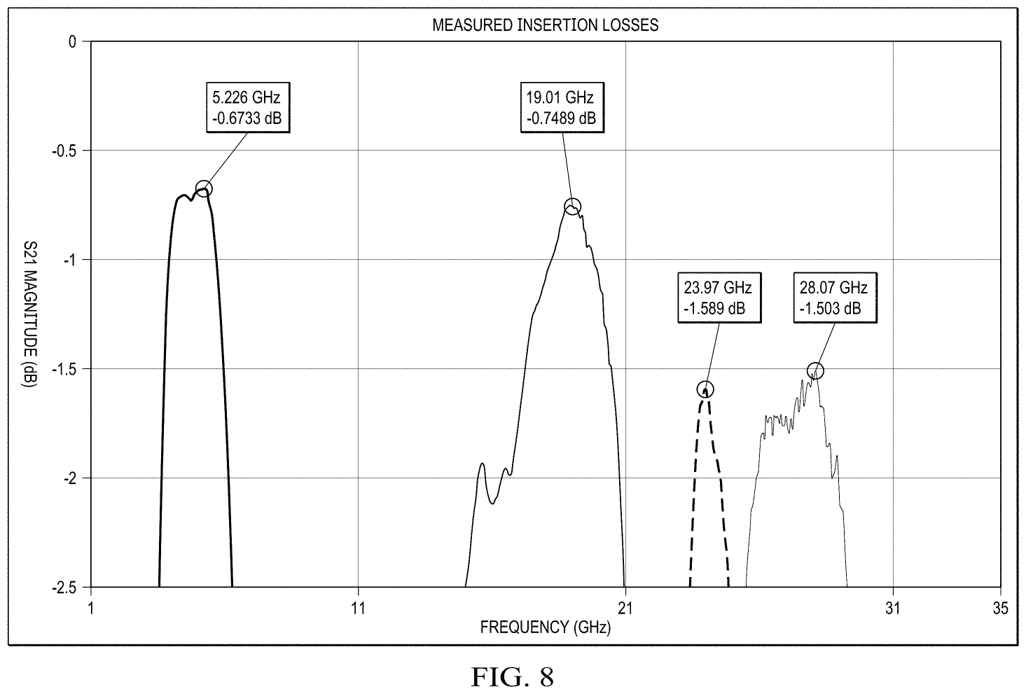

FIG. 8 is a graph that shows the insertion loss of SiP based Filters of the present invention.

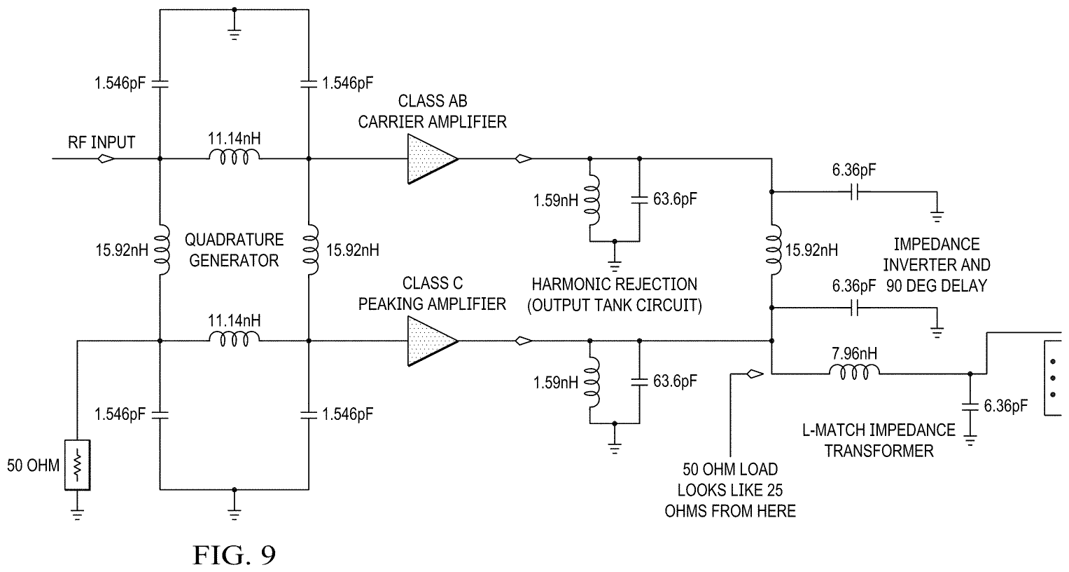

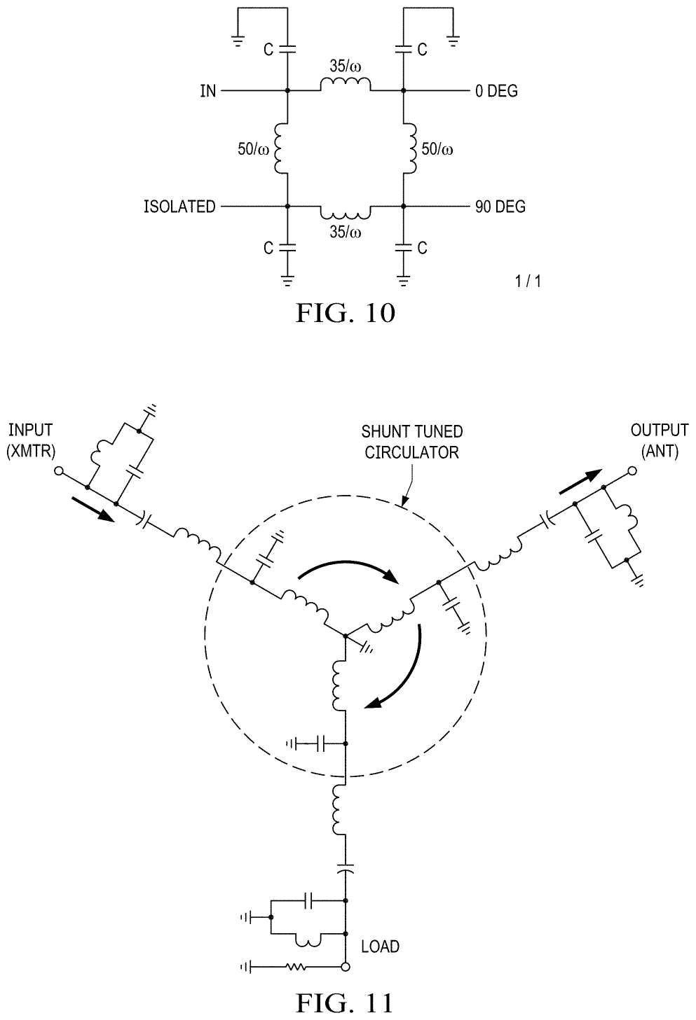

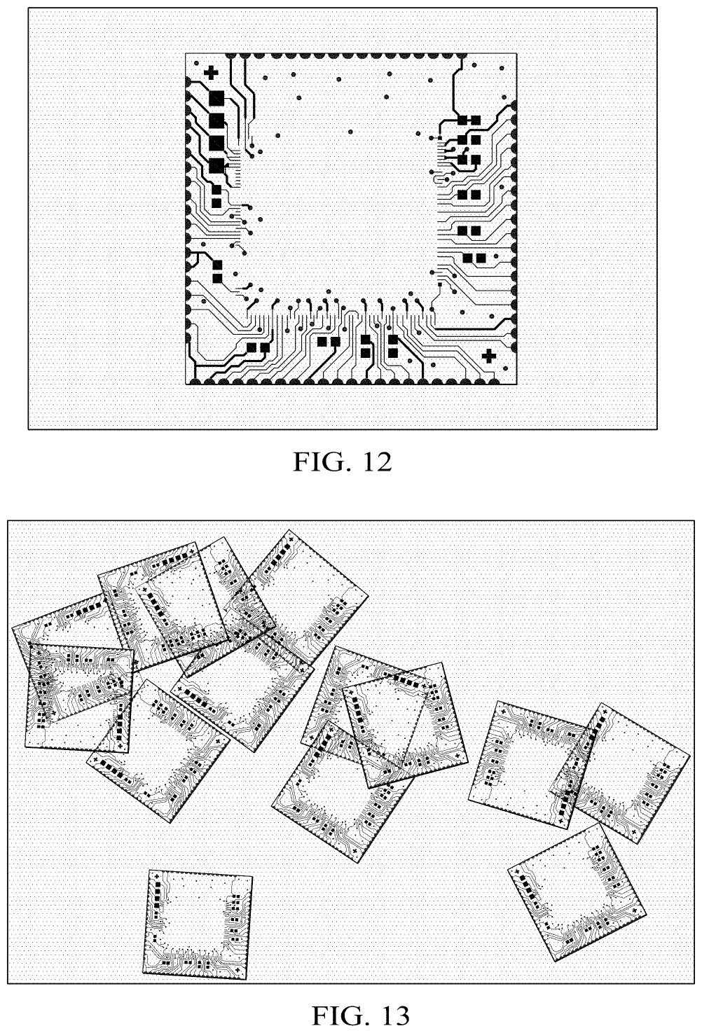

FIG. 9 shows a Doherty Amplifier design including the lumped elements that can be made using the present invention. FIG. 10 shows a power divider/combiner that can be made using the present invention. FIG. 11 shows a lumped element circulator when a termination resistor is connected to the circulator, it becomes an isolator and can be made using the present invention. FIG. 12 shows glass based SiP with integrated lumped element devices of the present invention. The SiP is approximately 0.5 cm×0.5 cm. FIG. 13 shows a sampling of glass based SiPs with integrated lumped element devices of the present invention. Depending on the size of the SiP there can be a great number of SiPs on a single wafer.

In particular a SiP with a integrated lump element RF device has been produced with design to device parity in APEX® Glass using conventional semiconductor processing equipment. The integrated lumped element RF filter in the APEX® Glass SiP can be seen in FIG. 12. The APEX® Glass SiP with the integrated lump element devices. The open area in the center of the SiP is for the placement of integrated circuits to complete the SiP. FIG. 13 shows a sampling of glass based SiP with integrated lumped element devices of the present invention. Depending of size of the SiP there can be a great number of SiPs on a single wafer. The APEX™ Glass wafer can be populated with over 500 SiP with the integrated lump element devices.

An SiP with a fully integrated lumped element device can be produced in photo-definable glasses having high temperature stability, good mechanical and electrical properties, and better chemical resistance than plastics and many metals. To our knowledge, the only commercial photo-definable glass is FOTURAN®, made by Schott Corporation. FOTURAN® comprises a lithium-aluminum-silicate glass containing traces of silver ions. When exposed to UV-light within the absorption band of cerium oxide, the cerium oxide acts as sensitizers, absorbing a photon and losing an electron that reduces neighboring silver oxide to form silver atoms, e.g.,

Ce3++Ag+=Ce4++Ag0

The silver atoms coalesce into silver nanoclusters during the baking process and induces nucleation sites for crystallization of the surrounding glass. If exposed to UV light through a mask, only the exposed regions of the glass will crystallize during subsequent heat treatment.

This heat treatment must be performed at a temperature near the glass transformation temperature (e.g., greater than 465° C. in air for FOTURAN®). The crystalline phase is more soluble in etchants, such as hydrofluoric acid (HF), than the unexposed vitreous, amorphous regions. In particular, the crystalline regions of FOTURAN® are etched about 20 times faster than the amorphous regions in 10% HF, enabling microstructures with wall slopes ratios of about 20:1 when the exposed regions are removed. See T. R. Dietrich et al., “Fabrication technologies for microsystems utilizing photoetchable glass,” Microelectronic Engineering 30, 497 (1996), which is incorporated herein by reference.

Preferably, the shaped glass structure contains at least one or more, two or three-dimensional inductive device. The inductive device is formed by making a series of connected loops to form a free-standing inductor. The loops can be either rectangular, circular, elliptical, fractal or other shapes that that generate induction. The patterned regions of the APEX® glass can be filled with metal, alloys, composites, glass or other magnetic media, by a number of methods including plating or vapor phase deposition. The magnetic permittivity of the media combined with the dimensions and number of structures (loops, turns or other inductive elements) in the device provide the inductance of devices.

FOTURAN is described in information supplied by Invenios (the U.S. supplier for) FOTURAN® is composed of silicon oxide (SiO₂) of 75 to 85% by weight, lithium oxide (Li₂O) of 7 to 11% by weight, aluminum oxide (Al₂O₃) of 3 to 6% by weight, sodium oxide (Na₂O) of 1 to 2% by weight, 0.2-0.5% by weight antimony trioxide (Sb₂O₃) or arsenic oxide (As₂O₃), silver oxide (Ag₂O) of 0.05 to 0.15% by weight, and cerium oxide (CeO₂) of 0.01 to 0.04% by weight.

As used herein the terms “APEX® Glass ceramic”, “APEX glass” or simply “APEX” is used to denote one embodiment of the glass ceramic composition of the present invention.

The present invention provides a single material approach for the fabrication of optical microstructures with photo-definable APEX glass for use in imaging applications by the shaped APEX glass structures that are used for lenses and includes through-layer or in-layer designs.

Generally, glass ceramics materials have had limited success in microstructure formation plagued by performance, uniformity, usability by others and availability issues. Past glass-ceramic materials have yielded etch aspect-ratios of approximately 15:1. In contrast, APEX® glass has an average etch aspect ratio greater than 50:1. This allows users to create smaller and deeper features. Additionally, our manufacturing process enables product yields of greater than 90% (legacy glass yields are closer to 50%). Lastly, in legacy glass ceramics, approximately only 30% of the glass is converted into the ceramic state, whereas with APEX® Glass ceramic this conversion is closer to 70%.

The APEX® Glass composition provides three main mechanisms for its enhanced performance: (1) The higher amount of silver leads to the formation of smaller ceramic crystals which are etched faster at the grain boundaries, (2) the decrease in silica content (the main constituent etched by the HF acid) decreases the undesired etching of unexposed material, and (3) the higher total weight percent of the alkali metals and boron oxide produces a much more homogeneous glass during manufacturing.

The present invention includes a method for fabricating a glass ceramic structure for use in forming inductive structures used in electromagnetic transmission, transformers and filtering applications. The present invention includes inductive structures created in the multiple planes of a glass-ceramic substrate with processes employing the (a) exposure to excitation energy such that the exposure occurs at various angles by either altering the orientation of the substrate or of the energy source, (b) a bake step and (c) an etch step. Angle sizes can be either acute or obtuse. The curved and digital structures are difficult, if not infeasible to create in most glass, ceramic or silicon substrates. The present invention has created the capability to create such structures in both the vertical as well as horizontal plane for glass-ceramic substrates. The present invention includes a method for fabricating of a inductive structure on or in a glass ceramic.

Ceramicization of the glass is accomplished by exposing the entire glass substrate to approximately 20 J/cm² of 310 nm light. When trying to create glass spaces within the ceramic, users expose all of the material, except where the glass is to remain glass. In one embodiment, the present invention provides a quartz/chrome mask containing a variety of concentric circles with different diameters.

The present invention includes a method for fabricating an inductive device in or on glass ceramic structure electrical microwave and radio frequency applications. The glass ceramic substrate may be a photosensitive glass substrate having a wide number of compositional variations including but not limited to: 60 to 76 weight % silica; at least 3 weight % K₂O with 6 to 16 weight % of a combination of K₂O and Na₂O; 0.003 to 1 weight % of at least one oxide selected from the group consisting of Ag₂O and Au₂O; 0.003 to 2 weight % Cu₂O; 0.75 to 7 weight % B₂O₃, and 6 to 7 weight % Al₂O₃, with the combination of B₂O₃; and Al₂O₃ not exceeding 13 weight %; 8 to 15 weight % Li₂O; and 0.001 to 0.1 weight % CeO₂. This and other varied composition are generally referred to as the APEX® glass.

The exposed portion may be transformed into a crystalline material by heating the glass substrate to a temperature near the glass transformation temperature. When etching the glass substrate in an etchant such as hydrofluoric acid, the anisotropic-etch ratio of the exposed portion to the unexposed portion is at least 30:1 when the glass is exposed to a broad spectrum mid-ultraviolet (about 308-312 nm) flood lamp to provide a shaped glass structure that has an aspect ratio of at least 30:1, and to create an inductive structure. The mask for the exposure can be of a halftone mask that provides a continuous grey scale to the exposure to form a curved structure for the creation an inductive structure/device. A halftone mask or grey scale enables the control the device structure by controlling the exposure intensity undercut of the ultraviolet light from the lamp. A digital mask can also be used with the flood exposure can be used to produce for the creation an inductive structure/device. The exposed glass is then typically baked in a two-step process: (1) heated between 420° C. and 520° C. for between 10 minutes to 2 hours, for the coalescing of silver ions into silver nanoparticles, and (2) heated between 520° C. and 620° C. for between 10 minutes and 2 hours, allowing the lithium oxide to form around the silver nanoparticles. The glass plate is then etched. The glass substrate is etched in an etchant of HF solution, typically 5% to 10% by volume, wherein the etch ratio of the exposed portion to that of the unexposed portion is at least 30:1 when exposed with a broad spectrum mid-ultraviolet flood light, and greater than 30:1 when exposed with a laser, to provide a shaped glass structure with an anisotropic-etch.

Although the present invention and its advantages have been described in detail, it should be understood that various changes, substitutions and alterations can be made herein without departing from the spirit and scope of the invention as defined by the appended claims. In some cases for the desired circuit performance or material compatibility, an SMD version of a resistor, capacitor, or inductor, can be used in lieu of one of the photo-definable glass based devices. Using an SMD version of one or more of the elements will contribute to the parasitic generated noise of the SiP, requiring extra care in the assembly and packaging. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

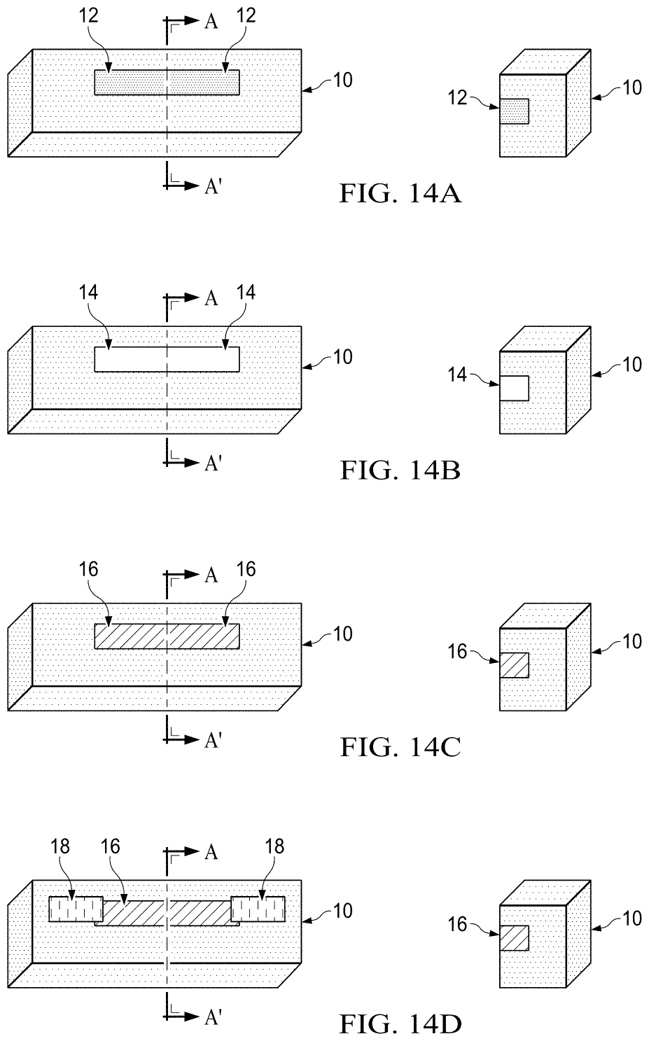

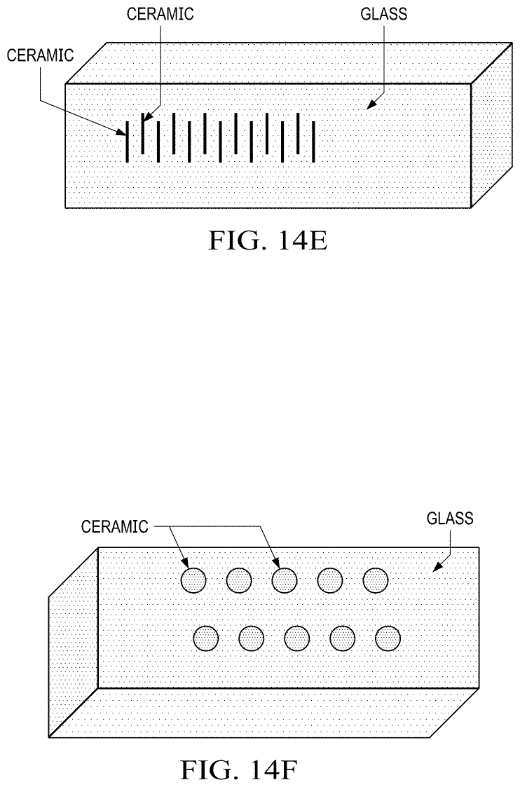

FIGS. 14A-14F show the process of making a device using the present invention. FIGS. 14A to 14D show one example of the present invention. FIG. 14A shows the starting material that is a photodefinable glass 10, which can be a wafer and may preferably be an APEX® Glass of, e.g., a 1 mm thickness with a surface roughness less than or equal to 50 nm and surface to surface parallel less than or equal to 10% with an RMS roughness <200 Å. In each of FIGS. 14A to 14D a top, isometric view is shown with a cross-sectional side view shown along dotted line A-A′. In this example, a resistor section of an SiP and its manufacture is shown. On a surface of the photodefinable glass wafer from Step 1, a photomask is deposited on the photodefinable glass 10 so the pattern of a trench/rectangle is formed, and the photodefinable glass 10 is exposed to a radiation at 310 nm with an intensity ˜20 J/cm2 and baked to create the exposure as described above. The width, length and depth of the exposure combined with the resistivity of the resistor media determine the resistor value. Both a top view and a cross-sectional side view are shown including a via pattern for the resistor. Exposure of the photodefinable glass 10 not covered by the mask creates a ceramic 12 in the photodefinable glass 10.

In FIG. 14B, the ceramic 12 that was formed in the prior step is further processed. The photodefinable glass 10 regions that have been converted to ceramic 12 are etched in a wet etch of HF acid as described above to form a trench 14.

In FIG. 14C, the etched regions of the photodefinable glass 10 are filled with a RF resistor paste or media 16 of Alumina, AlN, Be or other high frequency resistor material. The resistor paste or media 16 is deposited via a silk screening process. Excess paste is removed by a light DI water or IPA rinse and nylon wipe.

The photodefinable glass 10 wafer with the resistor paste 16 is then placed into an annealing oven with an inert environment such as Argon or a vacuum. The photodefinable glass 10 wafer is ramped to sinter the resistive material. Any excess resistor media on the surface can be removed by a 5 min CMP process with 2 μm Silica polishing media and water.

To connect the resistor, the photodefinable glass 10 is again coated with a standard photoresist. A pattern is exposed and developed following the standard process to create a pattern through the photoresists that a resistor layer can be deposited. The wafer is exposed to a light O₂ plasma to remove any residual organic material in the pattern. Typically this is accomplished at 0.1 mTorr with 200 W forward power for 1 min. Next, a metallization layer 18 is deposited, e.g., a thin film of tantalum, titanium TiN, TiW, NiCr or other similar media. Typically, the deposition is accomplished by a vacuum deposition. The vacuum deposition of a seed layer can be accomplished by DC sputtering of tantalum through a liftoff pattern on to the glass substrate at a rate of 40 Amin.

In another method, the photodefinable glass 10 wafer is coated with a standard photoresist. A pattern is exposed and developed following the standard process to create a pattern through the photoresists that a metallic seed layer can be deposited. The wafer is exposed to a light O₂ plasma to remove any residual organic material in the pattern. Typically this is accomplished at 0.1 mTorr with 200 W forward power for 1 min. A thin film seed layer of 400 Å of tantalum is deposited by a vacuum deposition. The vacuum deposition of a seed layer can be accomplished by DC sputtering of tantalum through a liftoff pattern on to the glass substrate at a rate of 40 Å/min.

In another embodiment, shown in FIG. 14E, a capacitor section of a SiP is formed using masks. On the surface of the photodefinable glass 10 wafer from Step 1, a photomask is used to image the capacitor at 310 nm light with an intensity of ˜20 J/cm2 to create a ladder shaped exposure in the photodefinable glass as described above. The spacing between the rungs in the ladder can range between 5% to 95%. This structure forms an interdigitated electrode based capacitor.

In another embodiment, shown in FIG. 14F, an inductor section of an SiP is formed using masks. On a surface adjacent to the capacitor or resistor on the photodefinable glass 10 wafer as described hereinabove, a photomask with the pattern of through-hole vias is made where one of the rows of via are offset by 30% to the other row. The via pattern is exposed at 310 nm radiation at an intensity of ˜20 J/cm2 to create the exposure as described above. This figures shows a top view of via pattern for the inductor.

The glass regions that have been converted to ceramic are etched in a wet etch of HF acid as described above. The photodefinable glass 10 wafer is the placed in a copper plating bath that preferentially plates the etched ceramic structure and completely fills the via and interdigitated line structure as described above.

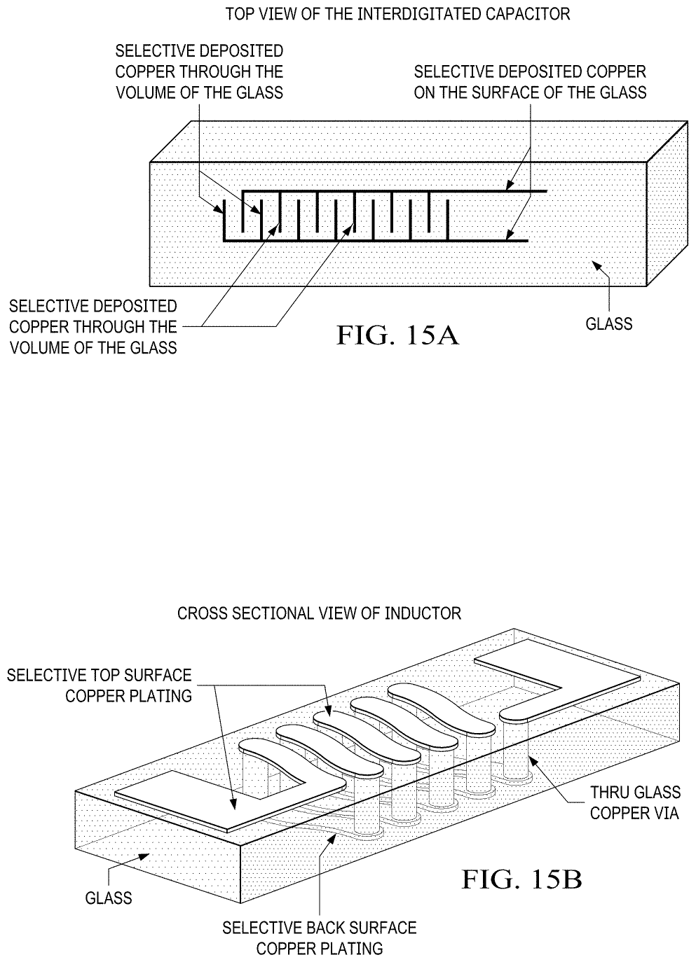

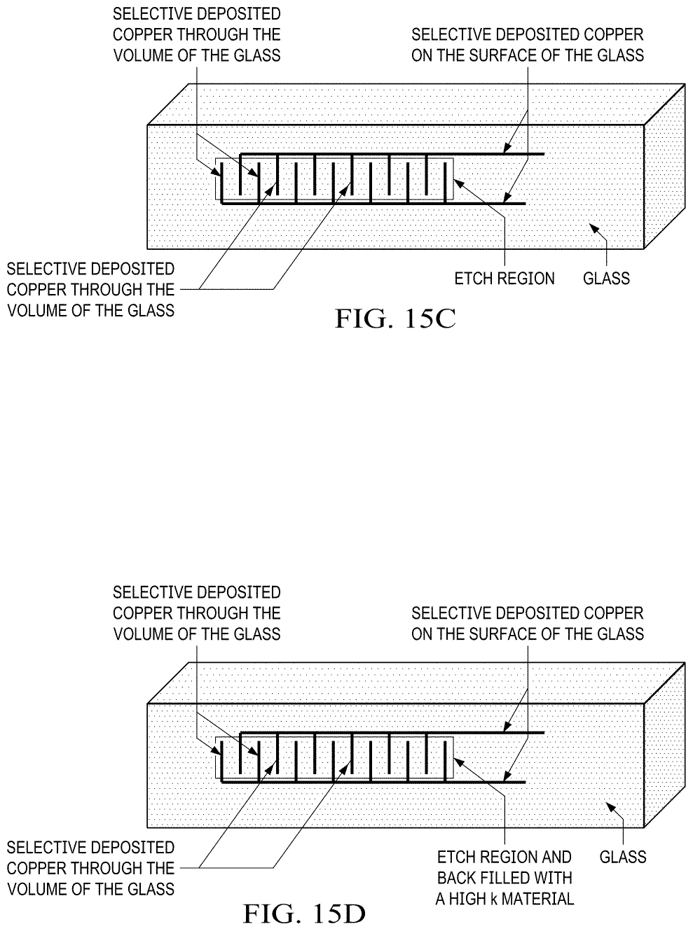

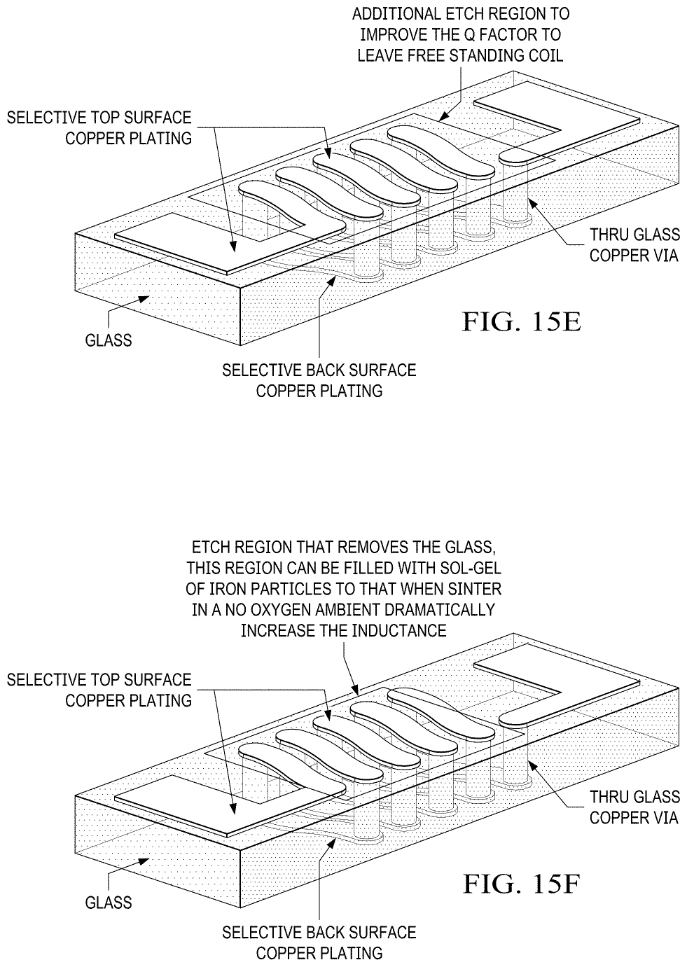

FIGS. 15A-15F show further processing steps for making a device using the present invention. FIG. 15A shows the copper filled through glass structures (via and interdigitated lines), and the APEX glass substrate is exposed using a second photo mask that has a patterns to connect the via for the inductors and finish the interdigitated pattern for the capacitor. FIG. 15B shows a cross-sectional view of the inductor. The intensity is of 310 nm light is 0.1 J/cm2, the wafer is the baked at 600° C. in argon for 30 min as described above. FIGS. 15A and 15B show that this converts the first few microns of the exposed glass to ceramic. The wafer is placed into a dilute HF bath exposing metallic silver. The wafer is then placed into a copper plating solution that selectively metallizes the exposed silver/etched regions. FIG. 15C shows the next step, in which an additional photo exposure and etch can be accomplished to remove the glass/ceramic material between the interdigitated electrodes of the capacitor to improve the Quality Factor or Q of the Capacitor. FIG. 15D shows the next step, in which an additional photo exposure and etch can be accomplished to remove the glass/ceramic material between the interdigitated electrodes and filled with a high k media to dramatically increase the capacitance to improve the Quality Factor of the capacitor. FIG. 15E shows the next step, in which an addition photo exposure and etch can be accomplished to remove the glass/ceramic material identified as the material within the rectangular outline of the inductor to enable the coils to be free standing to improve the Quality Factor or Q of the inductor. FIG. 15F shows the next step, in which an addition photo exposure and etch can be accomplished to remove the glass/ceramic material identified as the material within the rectangular outline or outside of the rectangular outline of the inductor. This region can be filled with magnetic particles that can be sintered under an inert gas to create an magnetic core inductor. This enables the integrated inductor to have much higher levels of inductance.

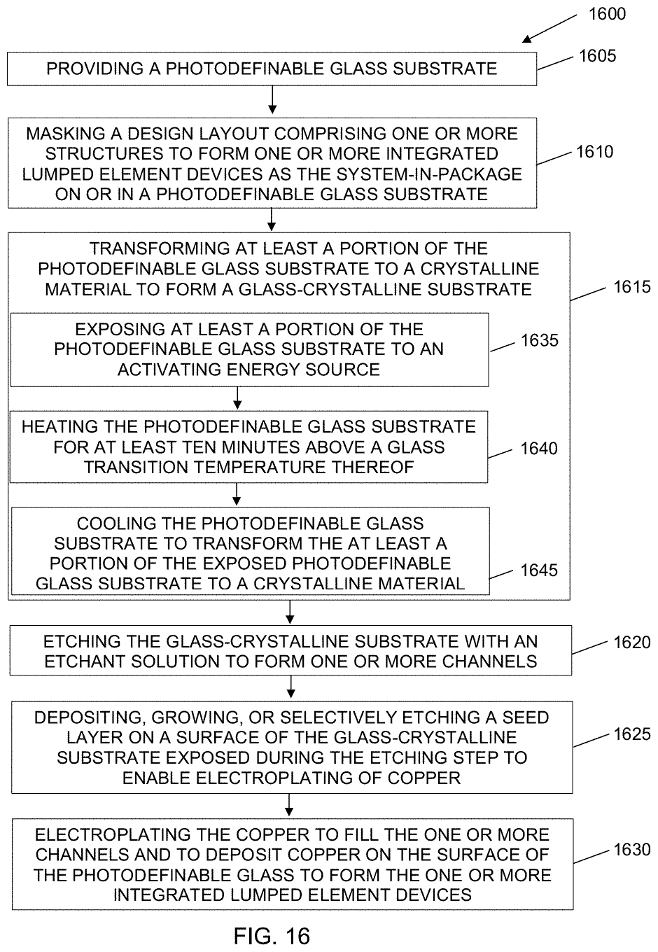

FIG. 16 shows a flowchart of a method embodiment of the invention. Method 1600 begins with block 1605, providing a photodefinable glass substrate. The step of masking a design layout comprising one or more structures to form one or more integrated lumped element devices as the system-in-package on or in a photodefinable glass substrate is shown on block 1610. Block 1615 includes transforming at least a portion of the photodefinable glass substrate to a crystalline material to form a glass-crystalline substrate. The step of etching the glass-crystalline substrate with an etchant solution to form one or more channels in the glass-crystalline substrate is shown in block 1620, and block 1625 shows depositing, growing, or selectively etching a seed layer on a surface of the glass-crystalline substrate exposed during the etching step to enable electroplating of copper to fill the one or more channels and to deposit the copper on the surface of the photodefinable glass to form the one or more integrated lumped element devices. The step of electroplating the copper to fill the one or more channels and to deposit copper on the surface of the photodefinable glass to form the one or more integrated lumped element devices is shown in block 1630. In one aspect, the embodiment includes the steps of exposing at least a portion of the photodefinable glass substrate to an activating energy source, shown in block 1635; heating the photodefinable glass substrate for at least ten minutes above a glass transition temperature thereof, shown in block 1640; and cooling the photodefinable glass substrate to transform the at least a portion of the exposed photodefinable glass substrate to a crystalline material to form the glass-crystalline substrate, shown in block 1645.

One embodiment of the invention, a method for creating a system-in-package formed in or on photodefinable glass, consists essentially of or consists of: providing a photodefinable glass substrate; masking a design layout including one or more structures to form one or more integrated lumped element devices as the system-in-package on or in a photodefinable glass substrate; transforming at least a portion of the photodefinable glass substrate to a crystalline material to form a glass-crystalline substrate; etching the glass-crystalline substrate with an etchant solution to form one or more channels in the glass-crystalline substrate; depositing, growing, or selectively etching a seed layer on a surface of the glass-crystalline substrate exposed during the etching step to enable electroplating of copper to fill the one or more channels and to deposit the copper on the surface of the photodefinable glass to form the one or more integrated lumped element devices; and electroplating the copper to fill the one or more channels and to deposit copper on the surface of the photodefinable glass to form the one or more integrated lumped element devices. In one aspect, the photodefinable glass substrate includes silica, lithium oxide, aluminum oxide, and cerium oxide. In another aspect, the method further includes converting the glass-crystalline substrate adjacent to the one or more channels to a ceramic phase. In another aspect, the step of transforming at least a portion of the photodefinable glass substrate includes: exposing at least a portion of the photodefinable glass substrate to an activating energy source; heating the photodefinable glass substrate for at least ten minutes above a glass transition temperature thereof; and cooling the photodefinable glass substrate to transform the at least a portion of the exposed photodefinable glass substrate to a crystalline material to form the glass-crystalline substrate. In another aspect, an anisotropic-etch ratio of an exposed portion to an unexposed portion is at least 30:1. In another aspect, the one or more integrated lumped system elements form an RF circuit that eliminates at least 25%, 30%, 35%, 40%, 45%, or 50% of an RF parasitic signal loss when compared to the equivalent surface-mounted device that is not on or in photodefinable glass. In another aspect, the one or more integrated lumped element devices form one or more isolators, one or more circulators, or one or more radio frequency (RF) filters including a low-pass filter, a high-pass filter, a notch filter, or a band-pass filter. In another aspect, the one or more integrated lumped system elements form one or more devices including an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer.

Another embodiment is a system-in-package made by a method consisting essentially of or consisting of: providing a photodefinable glass substrate; masking a design layout including one or more structures to form one or more integrated lumped element devices as the system-in-package on or in a photodefinable glass substrate; transforming at least a portion of the photodefinable glass substrate to a crystalline material to form a glass-crystalline substrate; etching the glass-crystalline substrate with an etchant solution to form one or more channels in the glass-crystalline substrate; depositing, growing, or selectively etching a seed layer on a surface of the glass-crystalline substrate exposed during the etching step to enable electroplating of copper to fill the one or more channels and to deposit the copper on the surface of the photodefinable glass to form the one or more integrated lumped element devices; and electroplating the copper to fill the one or more channels and to deposit copper on the surface of the photodefinable glass to form the one or more integrated lumped element devices. In one aspect, the photodefinable glass substrate includes silica, lithium oxide, aluminum oxide, and cerium oxide. In another aspect, the method further includes converting the glass-crystalline substrate adjacent to the one or more channels to a ceramic phase. In another aspect, the step of transforming at least a portion of the photodefinable glass substrate includes: exposing at least a portion of the photodefinable glass substrate to an activating energy source; heating the photodefinable glass substrate for at least ten minutes above a glass transition temperature thereof; and cooling the photodefinable glass substrate to transform the at least a portion of the exposed photodefinable glass substrate to a crystalline material to form the glass-crystalline substrate. In another aspect, an anisotropic-etch ratio of an exposed portion to an unexposed portion is at least 30:1. In another aspect, the one or more integrated lumped system elements form an RF circuit that eliminates at least 25%, 30%, 35%, 40%, 45%, or 50% of an RF parasitic signal loss when compared to the equivalent surface-mounted device that is not on or in photodefinable glass. In another aspect, the one or more integrated lumped element devices form one or more isolators, one or more circulators, or one or more radio frequency (RF) filters including a low-pass filter, a high-pass filter, a notch filter, or a band-pass filter. In another aspect, the one or more integrated lumped system elements form one or more devices including an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer.

Another embodiment, a system-in-package, consists essentially of or consists of: a photodefinable glass substrate; and one or more integrated lumped element devices comprising one or more resistors, one or more capacitors, one or more inductors, or a combination thereof formed on or in the photodefinable glass substrate as a system-in-package. In one aspect, the photodefinable glass substrate comprises silica, lithium oxide, aluminum oxide, and cerium oxide. In another aspect, the one or more integrated lumped element devices form one or more isolators, one or more circulators, or one or more radio frequency (RF) filters comprising a low-pass filter, a high-pass filter, a notch filter, or a band-pass filter. In another aspect, the one or more integrated lumped system elements form one or more devices comprising an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer. In another aspect, the one or more integrated lumped system elements form an RF circuit that eliminates at least 25%, 30%, 35%, 40%, 45%, or 50% of an RF parasitic signal loss when compared to an equivalent surface-mounted device that is not on or in photodefinable glass.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB.

Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. A method for creating a system-in-package formed in or on photodefinable glass comprising:
providing a photodefinable glass substrate;
masking a design layout comprising one or more structures to form one or more integrated lumped element devices as the system-in-package on or in a photodefinable glass substrate;
transforming at least a portion of the photodefinable glass substrate to a crystalline material to form a glass-crystalline substrate;
etching the glass-crystalline substrate with an etchant solution to form one or more channels in the glass-crystalline substrate;
depositing, growing, or selectively etching a seed layer on a surface of the glass-crystalline substrate exposed during the etching step to enable electroplating of copper to fill the one or more channels and to deposit the copper on the surface of the photodefinable glass to form the one or more integrated lumped element devices; and
electroplating the copper to fill the one or more channels and to deposit copper on the surface of the photodefinable glass to form the one or more integrated lumped element devices.

2. The method of claim 1, wherein the photodefinable glass substrate comprises silica, lithium oxide, aluminum oxide, and cerium oxide.

3. The method of claim 1, further comprising converting the glass-crystalline substrate adjacent to the one or more channels to a ceramic phase.

4. The method of claim 1, wherein the step of transforming at least a portion of the photodefinable glass substrate comprises:
exposing at least a portion of the photodefinable glass substrate to an activating energy source;
heating the photodefinable glass substrate for at least ten minutes above a glass transition temperature thereof; and
cooling the photodefinable glass substrate to transform the at least a portion of the exposed photodefinable glass substrate to a crystalline material to form the glass-crystalline substrate.

5. The method of claim 4, wherein an anisotropic-etch ratio of an exposed portion to an unexposed portion is at least 30:1.

6. The method of claim 1, wherein the one or more integrated lumped system elements form an RF circuit that eliminates at least 25%, 30%, 35%, 40%, 45%, or 50% of an RF parasitic signal loss when compared to the equivalent surface-mounted device that is not on or in photodefinable glass.

7. The method of claim 1, wherein the one or more integrated lumped element devices form one or more isolators, one or more circulators, or one or more radio frequency (RF) filters comprising a low-pass filter, a high-pass filter, a notch filter, or a band-pass filter.

8. The method of claim 1, wherein the one or more integrated lumped system elements form one or more devices comprising an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer.

9. A system-in-package made by a method comprising:
providing a photodefinable glass substrate;
masking a design layout comprising one or more structures to form one or more integrated lumped element devices as the system-in-package on or in a photodefinable glass substrate;
transforming at least a portion of the photodefinable glass substrate to a crystalline material to form a glass-crystalline substrate;
etching the glass-crystalline substrate with an etchant solution to form one or more channels in the glass-crystalline substrate; and
depositing, growing, or selectively etching a seed layer on a surface of the glass-crystalline substrate exposed during the etching step to enable electroplating of copper to fill the one or more channels and to deposit the copper on the surface of the photodefinable glass to form the one or more integrated lumped element devices; and
electroplating the copper to fill the one or more channels and to deposit copper on the surface of the photodefinable glass to form the one or more integrated lumped element devices.

10. The system-in-package of claim 9, wherein the photodefinable glass substrate comprises silica, lithium oxide, aluminum oxide, and cerium oxide.

11. The system-in-package of claim 9, wherein the step of transforming at least a portion of the photodefinable glass substrate comprises:
exposing at least a portion of the photodefinable glass substrate to an activating energy source;
heating the photodefinable glass substrate for at least ten minutes above a glass transition temperature thereof; and
cooling the photodefinable glass substrate to transform the at least a portion of the exposed photodefinable glass substrate to a crystalline material to form the glass-crystalline substrate.

12. The system-in-package of claim 11, wherein an anisotropic-etch ratio of an exposed portion to an unexposed portion is at least 30:1.

13. The system-in-package of claim 9, wherein the one or more integrated lumped system elements form an RF circuit that eliminates at least 25%, 30%, 35%, 40%, 45%, or 50% of an RF parasitic signal loss when compared to the equivalent surface-mounted device that is not on or in photodefinable glass.

14. The system-in-package of claim 9, wherein the one or more integrated lumped element devices form one or more isolators, one or more circulators, or one or more radio frequency (RF) filters comprising a low-pass filter, a high-pass filter, a notch filter, or a band-pass filter.

15. The system-in-package of claim 9, wherein the one or more integrated lumped system elements form one or more devices comprising an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer.

16. A system-in-package comprising:
a photodefinable glass substrate; and
one or more integrated lumped element devices comprising one or more resistors, one or more capacitors, one or more inductors, or a combination thereof formed on or in the photodefinable glass substrate as a system-in-package.

17. The system-in-package of claim 16, wherein the photodefinable glass substrate comprises silica, lithium oxide, aluminum oxide, and cerium oxide.

18. The system-in-package of claim 16, wherein the one or more integrated lumped element devices form one or more isolators, one or more circulators, or one or more radio frequency (RF) filters comprising a low-pass filter, a high-pass filter, a notch filter, or a band-pass filter.

19. The system-in-package of claim 16, wherein the one or more integrated lumped system elements form one or more devices comprising an antenna, an impedance matching element, a 50-ohm termination element, an integrated ground planes, an RF shielding element, an EMI shielding element, an RF combiner, an RF splitter, a power combiner, a power splitter, a transformer, a switch, or a diplexer.

20. The system-in-package of claim 16, wherein the one or more integrated lumped system elements form an RF circuit that eliminates at least 25%, 30%, 35%, 40%, 45%, or 50% of an RF parasitic signal loss when compared to an equivalent surface-mounted device that is not on or in photodefinable glass.
